(19) United States
(12) Patent Application Publication
(10) Pub. No.: US 2012/0048132 A1
(43) Pub. Date: Mar. 1, 2012

(54) METHOD AND APPARATUS FOR SCREEN PRINTING A MULTIPLE LAYER PATTERN

(75) Inventors: Andrea Baccini, Treviso (IT); Marco Galiazzo, Padova (pd) (IT)

(73) Assignee: APPLIED MATERIALS, INC., Santa Clara, CA (US)

(21) Appl. No.: 13/202,960

(22) PCT Filed: May 25, 2009
(86) PCT No.: PCT/EP2009/056324

§ 371 Date: Nov. 7, 2011

(30) Foreign Application Priority Data
Feb. 23, 2009 (IT) UD2009A000044

(51) Int. Cl. B41L 13/04

(52) U.S. Cl. 101/118

(57) ABSTRACT

Embodiments of the invention generally provide apparatus and methods of screen printing a multiple layer pattern on a substrate. In one embodiment, a first layer of a pattern is printed onto a surface of a substrate along with a plurality of alignment marks. The locations of the alignment marks are measured with respect to a feature of the substrate to determine the actual location of the pattern. The actual location is compared with the expected location to determine the positional error of the pattern placement on the substrate. This information is used to adjust the placement of the next layer of the pattern to be printed onto the first layer for more accurate placement and reduced positional error.

### BACKGROUND OF THE INVENTION

1. Field of the Invention

Embodiments of the present invention generally relate to a system and process for screen printing a multiple layer pattern on a surface of a substrate.

2. Description of the Related Art

Solar cells are photovoltaic (PV) devices that convert sunlight directly into electrical power. Solar cells typically have one or more p-n junctions. Each p-n junction comprises two different regions within a semiconductor material where one side is denoted as the p-type region and the other as the n-type region. When the p-n junction of a solar cell is exposed to sunlight (consisting of energy from photons), the sunlight is directly converted to electricity through the PV effect. Solar cells generate a specific amount of electric power and are tiled into modules sized to deliver the desired amount of system power. Solar modules are joined into panels with specific frames and connectors. Solar cells are commonly formed on silicon substrates, which may be single or multicrystalline silicon substrates. A typical solar cell includes a silicon wafer, substrate, or sheet typically less than about 0.3 mm thick with a thin layer of n-type silicon on top of a p-type region formed on the substrate.

The PV market has experienced growth at annual rates exceeding 30% for the last ten years. Some articles suggest that solar cell power production world-wide may exceed 10 GWp in the near future. It is estimated that more than 95% of all solar modules are silicon wafer based. The high market growth rate in combination with the need to substantially reduce solar electricity costs has resulted in a number of serious challenges for inexpensively forming high quality solar cells. Therefore, one major component in making commercially viable solar cells lies in reducing the manufacturing costs required to form the solar cells by improving the device yield and increasing the substrate throughput.

Screen printing has long been used in printing designs on objects, such as cloth or ceramics, and is used in the electronics industry for printing electrical component designs, such as electrical contacts or interconnects on the surface of a substrate. State of the art solar cell fabrication processes also use screen printing processes. In some applications, it is desirable to print contact lines on solar cell substrates having higher aspect ratios (i.e. ratio of line height to line width) than is possible with printing a single layer pattern to increase the current carrying capacity of the contacts. In order to meet this need, screen printing a double layered pattern has been attempted to increase the aspect ratio of the printed lines. However, the misalignment of a second layer of a screen printing pattern on an existing layer of the screen printing pattern due to errors in the positioning of the substrate on an automated transferring device, defects in the edge of the substrate, or shifting of the substrate on the automated transferring device can lead to poor device performance and low device efficiency.

Therefore, there is a need for a screen printing apparatus for the production of solar cells, electronic circuits, or other useful devices that has an improved method of controlling the alignment of double layered screen printing patterns on a substrate within the system.

### SUMMARY OF THE INVENTION

In one embodiment of the present invention, a screen printing process comprises receiving a substrate having a first layer of a pattern printed onto a surface of the substrate, wherein the pattern includes at least two alignment marks, determining the actual position of the at least two alignment marks with respect to at least one feature of the substrate, comparing the actual position of the at least two alignment marks with an expected position of the at least two alignment marks, determining an offset between the actual position and the expected position of the at least two alignment marks, adjusting a screen printing device to account for the determined offset, and printing a second layer of the pattern onto the first layer of the pattern.

In another embodiment of the present invention, a screen printing process comprises printing a first layer of a pattern onto a surface of a substrate with a screen printing device, wherein the pattern comprises a structure of conductive thin lines and at least two alignment marks, moving the substrate under an optical inspection assembly, capturing an optical image of the first layer of the pattern, determining the actual position of the at least two alignment marks with respect to at least one feature of the substrate, comparing the actual position of the at least two alignment marks with an expected position of the at least two alignment marks, determining an offset between the actual position and the expected position, adjusting the screen printing device to account for the determined offset, and printing a second layer of the pattern onto the first layer of the pattern via the adjusted screen printing device.

In yet another embodiment of the present invention, a screen printing system comprises a rotary actuator having a printing nest disposed thereon and movable between a first position, a second position, and a third position, an input conveyor positioned to load a substrate onto the printing nest in the first position, a screen printing chamber having an adjustable screen printing device disposed therein, the screen printing chamber positioned to print a pattern onto the substrate when the printing nest is in the second position, wherein the pattern comprises a conductive structure of thin lines and at least two alignment marks, an optical inspection assembly having a camera and a lamp, the optical inspection assembly positioned to capture optical images of a first layer of the pattern when the printing nest is in the first position, an exit conveyor positioned to unload the substrate when the printing nest is in the third position, and a system controller comprising software configured to determine an offset of an actual position of the alignment marks captured in the optical image of the first layer of the pattern with respect to an expected position of the alignment marks and adjust the screen printing device to account for the determined offset prior to printing a second layer of the pattern on the first layer of the pattern.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic isometric view of a system that may be used in conjunction with embodiments of the present invention to form multiple layers of a desired pattern.

FIG. 1B is a schematic top plan view of the system in FIG. 1A.

FIG. 2A is a plan view of a front surface, or light receiving surface, of a solar cell substrate.

FIG. 2B is a schematic cross-sectional view of a portion of a solar cell substrate having a properly aligned second layer printed atop a first layer.

FIG. 2C is a schematic isometric view of a solar cell substrate illustrating misalignment of screen printing layers.

FIG. 3A illustrates various examples of alignment marks to be printed on a substrate according to one embodiment of the present invention.

FIGS. 3B-3D illustrate various configurations of alignment marks on a front surface of a substrate according to embodiments of the present invention.

FIG. 4A is a schematic isometric view of one embodiment of a rotary actuator assembly that illustrates a configuration in which an inspection assembly is positioned to inspect the front surface of the substrate.

FIG. 4B illustrates an embodiment of the rotary actuator assembly for controlling illumination of the front surface of the substrate.

FIG. 5 is a schematic isometric view of one embodiment of the rotary actuator assembly in which the inspection assembly includes a plurality of optical inspection devices.

FIG. 6 is a schematic diagram of an operational sequence for accurately screen printing a double layered pattern on the front surface of the substrate 150 according to one embodiment of the present invention.

FIG. 7 is a top plan view of a system that may be used in conjunction with embodiments of the present invention to form multiple layers of a desired pattern.

### DETAILED DESCRIPTION

Embodiments of the present invention provide an apparatus and method for processing substrates in a screen printing system that utilizes an improved substrate transferring, aligning, and screen printing process that can improve the device yield performance and cost-of-ownership (CoO) of a substrate processing line. In one embodiment, the screen printing system, hereafter system, is adapted to perform a screen printing process within a portion of a crystalline silicon solar cell production line in which a substrate is patterned with a desired material in two or more layers and is then processed in one or more subsequent processing chambers. The subsequent processing chambers may be adapted to perform one or more bake steps and one or more cleaning steps. In one embodiment, the system is a module positioned within the Softline™ tool available from Baccini S.p.A., which is owned by Applied Materials, Inc. of Santa Clara, Calif. While the discussion below primarily discusses the processes of screen printing a pattern, such as an interconnect or contact structure, on a surface of a solar cell device this configuration is not intended to be limiting as to the scope of the invention described herein.

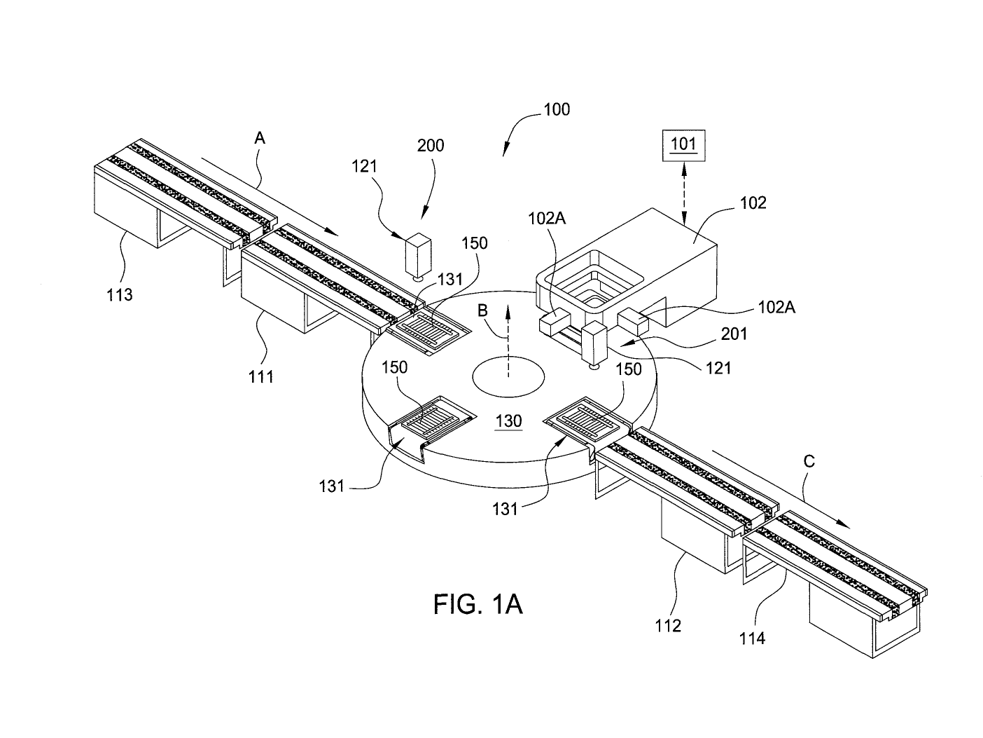

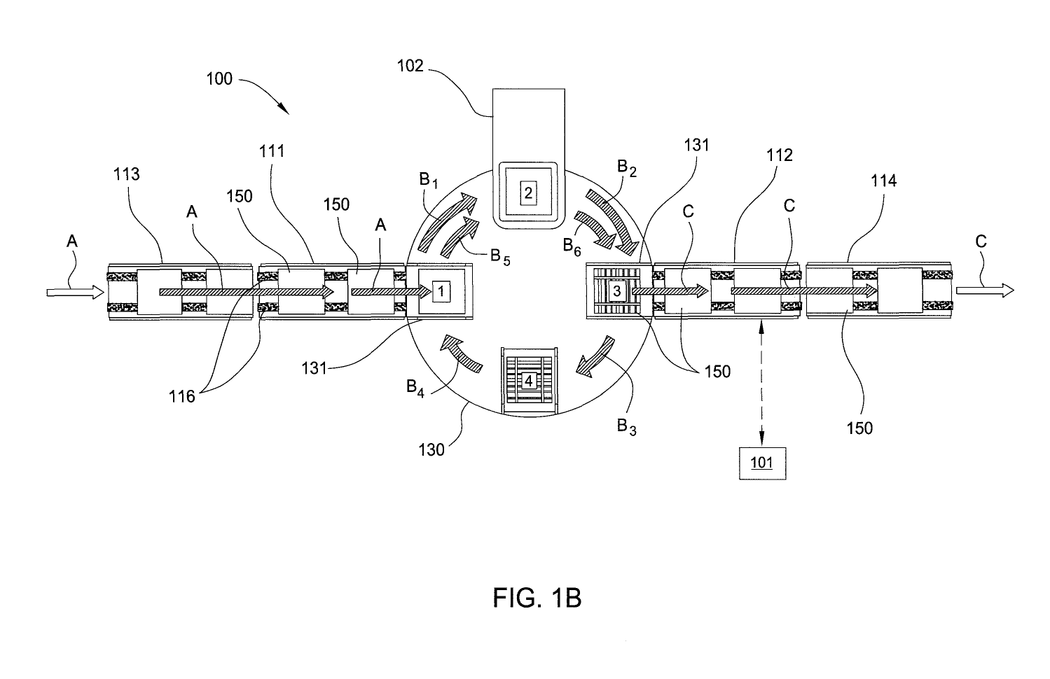

FIG. 1A is a schematic isometric view and FIG. 1B is a schematic top plan view illustrating one embodiment of a screen printing system, or system 100, that may be used in conjunction with embodiments of the present invention to form multiple layers of a desired pattern on a surface of a solar cell substrate 150. In one embodiment, the system 100 comprises an incoming conveyor 111, a rotary actuator assembly 130, a screen print chamber 102, and an outgoing conveyor 112. The incoming conveyor 111 may be configured to receive a substrate 150 from an input device, such as an input conveyor 113, and transfer the substrate 150 to a printing nest 131 coupled to the rotary actuator assembly 130. The outgoing conveyor 112 may be configured to receive a processed substrate 150 from a printing nest 131 coupled to the rotary actuator assembly 130 and transfer the substrate 150 to a substrate removal device, such as an exit conveyor 114. The input conveyor 113 and the exit conveyor 114 may be automated substrate handling devices that are part of a larger production line. For example, the input conveyor 113 and the exit conveyor 114 may be part of the Softline™ tool, of which the system 100 may be a module.

As shown in FIG. 1A, the rotary actuator assembly 130 may be rotated and angularly positioned about the “B” axis by a rotary actuator (not shown) and a system controller 101, such that the printing nests 131 may be selectively angularly positioned within the system 100. The rotary actuator assembly 130 may also have one or more supporting components to facilitate the control of the print nests 131 or other automated devices used to perform a substrate processing sequence in the system 100.

In one embodiment, the rotary actuator assembly 130 includes four printing nests 131, or substrate supports, that are each adapted to support a substrate 150 during the screen printing process performed within the screen printing chamber 102. FIG. 1B schematically illustrates the position of the rotary actuator assembly 130 in which one printing nest 131 is in position “1” to receive a substrate 150 from the input conveyor 113, another printing nest 131 is in position “2” within the screen printing chamber 102 so that another substrate 150 can receive a screen printed pattern on a surface thereof, another printing nest 131 is in position “3” for transferring a processed substrate 150 to the output conveyor 112, and another printing nest 131 is in position “4”, which is an intermediate stage between position “1” and position “3”.

In one embodiment, the screen printing chamber 102 in system 100 uses a conventional screen printing device available from Baccini S.p.A., which is adapted to deposit material in a desired pattern on the surface of the substrate 150 positioned on the printing nest 131 in position “2” during the screen printing process. In one embodiment, the screen printing chamber 102 contains a plurality of actuators, for example, actuators 102A (e.g., stepper motors, servo-motors) that are in communication with the system controller 101 and are used to adjust the position and/or angular orientation of the screen printing device with respect to the substrate via commands sent from the system controller 101. In one embodiment, the screen printing chamber 102 is adapted to deposit a metal containing or dielectric containing material on the solar cell substrate 150. In one embodiment, the solar cell substrate 150 has a width between about 125 mm and about 156 mm and a length between about 70 mm and about 156 mm.

In one embodiment, the system 100 includes an inspection assembly 200 adapted to inspect a substrate 150 located on the printing nest 131 in position “1”. The inspection assembly 200 may include one or more cameras 121 positioned to inspect an incoming, or processed substrate 150, located on the printing nest 131 in position “1”. In one embodiment, the inspection assembly 200 includes at least one camera 121 (e.g., CCD camera) and other electronic components capable of inspecting and communicating the inspection results to the system controller 101 used to analyze the orientation and position of the substrate 150 on the printing nest 131.

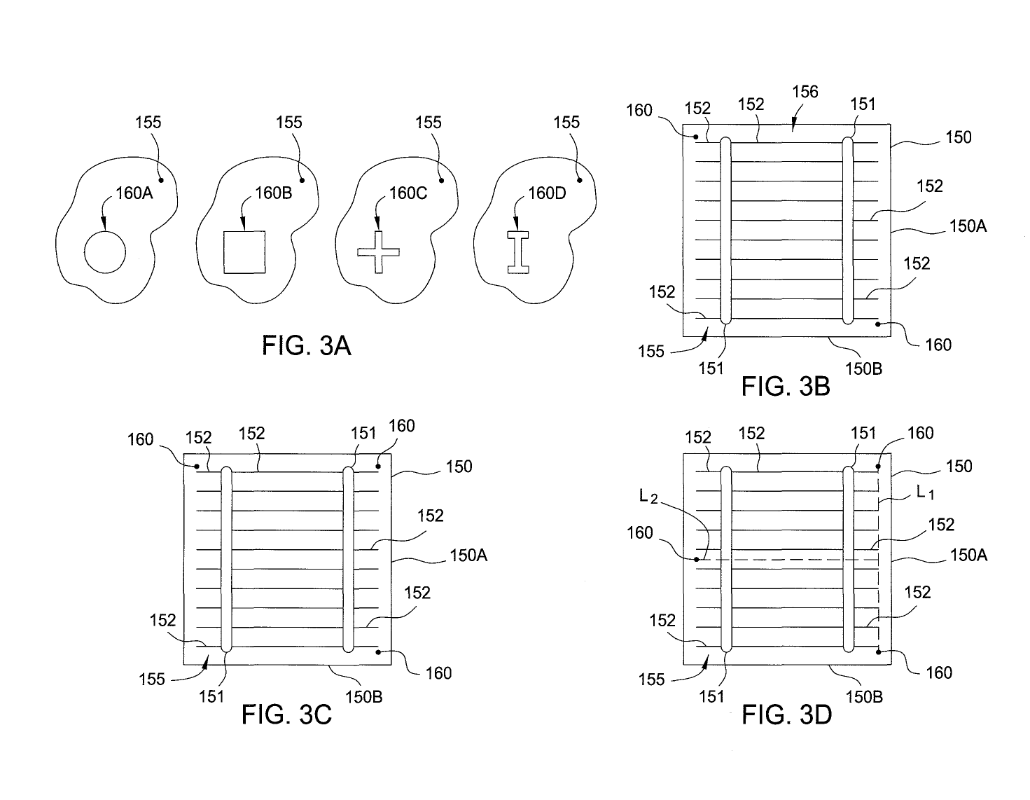

The system controller 101 facilitates the control and automation of the overall system 100 and may include a central processing unit (CPU) (not shown), memory (not shown), and support circuits (or I/O) (not shown). The CPU may be one of any form of computer processors that are used in industrial settings for controlling various chamber processes and hardware (e.g., conveyors, detectors, motors, fluid delivery hardware, etc.) and monitor the system and chamber processes (e.g., substrate position, process time, detector signal, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 101 determines which tasks are performable on a substrate. Preferably, the program is software readable by the system controller 101, which includes code to generate and store at least substrate positional information, the sequence of movement of the various controlled components, substrate inspection system information, and any combination thereof. In one embodiment of the present invention, the system controller 101 includes pattern recognition software to resolve the positions of alignment marks as subsequently described with respect to FIGS. 3A-3D.

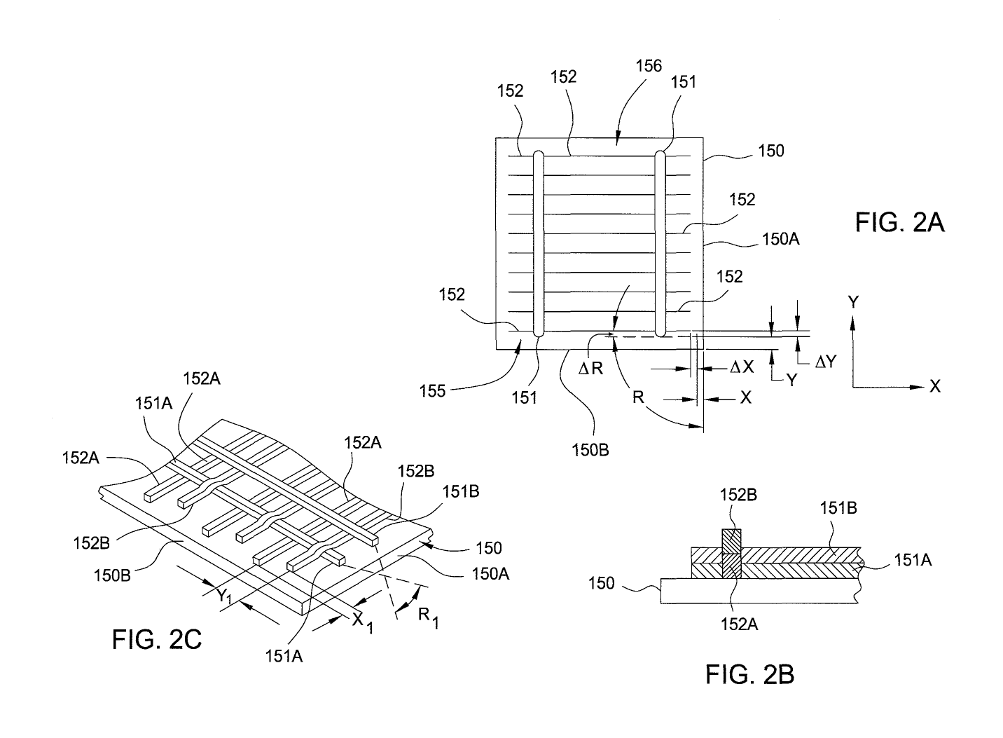

FIG. 2A is a plan view of a front surface 155, or light receiving surface, of a solar cell substrate 150. Electrical current generated by the junction formed in a solar cell when illuminated flows through a front contact structure 156 disposed on the front surface 155 of the solar cell substrate 150 and a back contact structure (not shown) disposed on the back surface (not shown) of the solar cell substrate 150. The front contact structure 156, as shown in FIG. 2A, may be configured as widely-spaced thin metal lines, or fingers 152, that supply current to larger bus bars 151. Typically, the front surface 155 is coated with a thin layer of dielectric material, such as silicon nitride (SiN), which acts as an antireflection coating (ARC) to minimize light reflection. The back contact structure (not shown) is generally not constrained to thin metal lines since the back surface of the solar cell substrate 150 is not a light receiving surface.

In one embodiment, the placement of the buss bars 151 and the fingers 152 on the front surface 155 of the substrate 150 depends on the alignment of a screen printing device used in the screen printing chamber 102 (FIG. 1A) with respect to the positioning of the substrate 150 on the printing nest 131. The screen printing device is generally a sheet or plate contained in the screen printing chamber 102 that has a plurality of holes, slots, or other features formed therein to define the pattern and placement of screen printed ink or paste on the front surface 155 of the substrate 150. Typically, the alignment of the screen printed pattern of fingers 152 and buss bars 151 on the surface of the substrate 150 is dependent on the alignment of the screen printing device to an edge of the substrate 150. For instance, the placement of a single layer screen printed pattern of buss bars 151 and fingers 152 may have an expected position X and an expected angle orientation R with respect to an edge 150A and an expected position Y with respect to an edge 150B of the substrate 150 as shown in FIG. 2A. The positional error of the single layer of the screen printed pattern of fingers 152 and buss bars 151 on the front surface 155 of the substrate 150 from the expected position (X, Y) and the expected angular orientation R on the front surface 155 of the substrate 150 may be described as a positional offset (ΔX, ΔY) and an angular offset ΔR. Thus, the positional offset (ΔX, ΔY) is the error in the placement of the pattern of buss bars 151 and fingers 152 relative to the edges 150A and 150B, and the angular offset ΔR is the error in the angular alignment of the printed pattern of buss bars 151 and fingers 152 relative to the edge 150B of the substrate 150. The misplacement of a single layer of the screen printed pattern of buss bars 151 and fingers 152 on the front surface 155 of the substrate 150 can affect the ability of the formed device to perform correctly and thus affect the device yield of the system 100. However, minimizing positional errors becomes even more critical in applications having multiple layers of the screen printing pattern printed atop one another.

In an effort to increase the current carrying capacity of the front contact structure 156 without reducing the efficiency of a completed solar cell, the height of the buss bars 151 and fingers 152 may be increased without increasing their thickness by screen printing the pattern of buss bars 151 and fingers 152 in two or more successive layers. FIG. 2B is a schematic side cross-sectional view of a portion of the substrate 150 having a properly aligned second layer of buss bars 151B and fingers 152B printed atop a first layer of buss bars 151A and fingers 152A.

FIG. 2C is a schematic isometric view of the solar cell substrate 150 illustrating misalignment of screen printing layers. Typically, the alignment of the screen printed pattern for the second layer onto the first layer is dependent on the alignment of the screen printing device with respect to edges 150A, 150B of the substrate 150 as shown in FIG. 2A. However, misalignment of the second layer with respect to the first layer may occur due to a change in the positioning of the substrate 150 and/or the compounded effect of the measurement tolerances between the first screen printing operation and successive screen printing operations. In general, the misalignment of the second layer of fingers 152B and buss bars 151B with respect to the first layer of fingers 152A and buss bars 151A can be described as a positional misalignment (X1, Y1) and an angular misalignment R1. The positional and angular misalignment of the second layer of the screen printing pattern with respect to the first layer of the screen printed pattern may reduce the device performance and the device efficiency due to covering or shadowing more of the front surface 155 than would a single layer pattern, resulting in an overall reduction in the device yield of the system 100.

In an effort to improve the accuracy with which the second layer of the screen printed pattern is aligned with the first layer of the screen printed pattern, embodiments of the invention utilize one or more optical inspection devices, the system controller 101, and one or more alignment marks, which are formed on the front surface 155 of the substrate 150 during the printing of the first layer of the screen printed pattern to automatically adjust the alignment of a second layer of the screen printed pattern with respect to the first layer of the screen printed pattern. In one embodiment, the second layer of buss bars 151B and fingers 152B is aligned in an automated fashion to the first layer of buss bars 151A and fingers 152A by use of the information received by the system controller 101 from the one or more optical inspection devices and the ability of the system controller to control the position and orientation of the screen printing device relative to the first layer of buss bars 151A and fingers 152A. The screen printing device may be coupled to one or more actuators 102A adapted to position and orient the screen printing device to a desired position within the screen printing chamber 102 in an automated fashion. In one embodiment, the optical inspection device includes one or more components contained in the inspection assembly 200. In one embodiment, the one or more alignment marks, or fiducial marks, may include the alignment marks 160 illustrated in FIGS. 3A-3D described below.

FIG. 3A illustrates various examples of alignment marks 160, for example alignment marks 160A-160D, that may be formed on the front surface 155 of the substrate 150 during a screen printing process of the first layer of buss bars 151A and fingers 152A and used by the inspection assembly 200 to find the positional offset (ΔX, ΔY) and the angular offset ΔR of the first layer of buss bars 151A and fingers 152A screen printed on the front surface 155 of the substrate 150. In one embodiment, the alignment marks 160 are printed on unused areas of the front surface 155 of the substrate 150 to prevent the alignment marks 160 from affecting the performance of the formed solar cell device. In one embodiment, the alignment marks 160 may have a circular shape (e.g., alignment mark 160A), a rectangular shape (e.g., alignment mark 160B), a cross shape (e.g., alignment mark 160C), or an alphanumeric shape (e.g., alignment mark 160D). It is generally desirable to select an alignment mark 160 shape that allows the pattern recognition software found in the system controller 101 to resolve the actual position of the alignment mark 160, and thus the actual position of the first layer of the screen printed pattern of buss bars 151A and fingers 152A, on the front surface 155 of the substrate 150 from the image viewed by the inspection assembly 200. The system controller 101 may then resolve the positional offset (ΔX, ΔY) from the expected position (X, Y) and the angular offset ΔR from the expected angular orientation R and adjust the screen printing device to minimize the positional misalignment (X1, Y1) and an angular misalignment R1 when printing the second layer of buss bars 151B and fingers 152B.

FIGS. 3B-3D illustrate various configurations of alignment marks 160 on the front surface 155 of the substrate 150 that may be used to improve the accuracy of the offset measurements calculated by the system controller 101 from the images received by the inspection assembly 200. FIG. 3B illustrates one configuration in which two alignment marks 160 are placed near opposite corners on the front surface 155 of the substrate 150. In this embodiment, by spreading the alignment marks 160 as far apart as possible, the relative error to a feature on the substrate 150, such as the edge 150A or 150B, may be more accurately resolved. FIG. 3C illustrates another configuration in which three alignment marks 160 are printed on the front surface 155 of the substrate 150 near various corners to help resolve the offset of the first layer of the pattern of buss bars 151A and fingers 152A.

FIG. 3D illustrates another configuration in which three alignment marks 160 are printed in strategic positions across the front surface 155 of the substrate 150. In this embodiment, two of the alignment marks 160 are positioned in a line parallel to the edge 150A, and the third alignment mark 160 is positioned a distance perpendicular to the edge 150A. In this embodiment, the pattern recognition software in the system controller 101 creates perpendicular reference lines L1 and L2 to provide additional information about the position and orientation of the first layer of buss bars 151A and fingers 152A relative to the substrate 150.

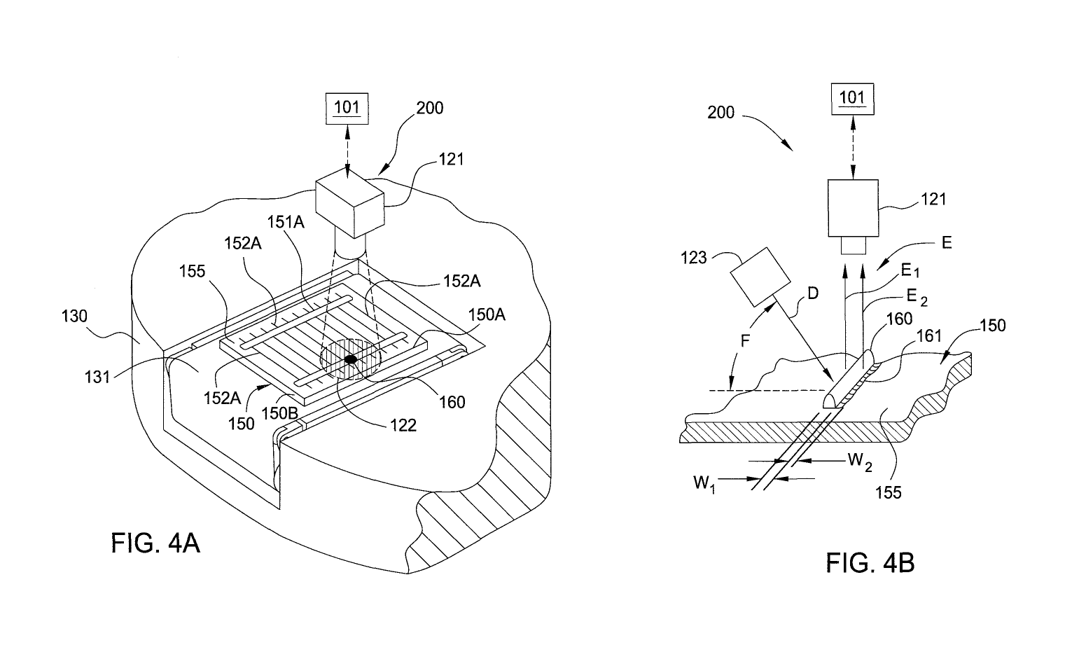

FIG. 4A is a schematic isometric view of one embodiment of the rotary actuator assembly 130 that illustrates a configuration in which the inspection assembly 200 is positioned to inspect the front surface 155 of the substrate 150 disposed on the printing nest 131. In one embodiment, a camera 121 is positioned over the front surface 155 of the substrate 150 so that a viewing area 122 of the camera 121 can inspect at least one region of the surface 155 on the substrate 150. In one embodiment, the viewing area 122 is positioned so that it views one or more alignment marks 160 and a feature of the substrate 150, such as the substrate edge 150A, to provide information to the system controller 101 regarding the offset of the screen printed pattern of a first layer of buss bars 151A and fingers 152A. In one embodiment, the viewing area 122 is positioned so that it views multiple features on the substrate 150, such as edges 150A and 150B, and one or more alignment marks 160 to provide coordinate information regarding the positional offset of the alignment marks 160 from the ideal position and thus the positional offset (ΔX, ΔY) and the angular offset ΔR of the first layer of buss bars 151A and fingers 152A on the front surface 155 of the substrate 150. Therefore, the alignment of each of the printing nests 131 positioned within the rotary actuator assembly 130 and the screen printing chamber 102 components are separately adjusted, since the position of each of the printing nests 131 relative to the rotary actuator assembly 130, input conveyor 111, and printing chamber 102 each vary.

FIG. 4B illustrates an embodiment of the optical inspection assembly 200 for controlling illumination of the front surface 155 of the substrate 150 in order to improve the accuracy of the positional information received by the camera 121. In one embodiment, a lamp 123 may be oriented so that a shadow 161 created by the blockage of the projected light “D” from the lamp 123 by the alignment mark 160 is minimized. In general, the shadow 161 may affect the measured sized of the alignment mark 160, since the reflected light E contains at least a first component E1 reflected from the alignment mark 160 and a second component E2 reflected from the shadow region 161. The shadow 161 may affect the ability of the camera 121 to discern between the true width W1 of the alignment mark 160 and the apparent width W1+W2 of the alignment mark 160.

Therefore, it may be desirable to orient the lamp 123 as close to normal (i.e., 90 degrees) to the front surface 155 of the substrate 150 as possible to reduce the size of the shadow 161. In one embodiment, the lamp 123 is oriented at an angle F from between about 80 degrees and about 100 degrees. In another embodiment, the lamp 123 is oriented at an angle F from between about 85 degrees and about 95 degrees.

In one embodiment, it is also desirable to control the wavelength of light that is delivered from the lamp 123 to help improve the ability of the optical inspection system 200 to accurately resolve the position of the alignment mark 160 on the front surface 155 of the substrate 150. In one embodiment, the lamp 123 uses a red LED to illuminate the front surface 155 of the substrate 150. A red LED light may be especially effective when the first layer of buss bars 151A and fingers 152A are printed on a silicon nitride (SiN) antireflection coating (ARC) layer that is typically formed on the front surface 155 of a solar cell substrate 150. In one embodiment, it is desirable to position the viewing area 122 of the camera 121 on the alignment mark 160 printed in an area where the ARC is formed on the front surface 155 of the substrate 150.

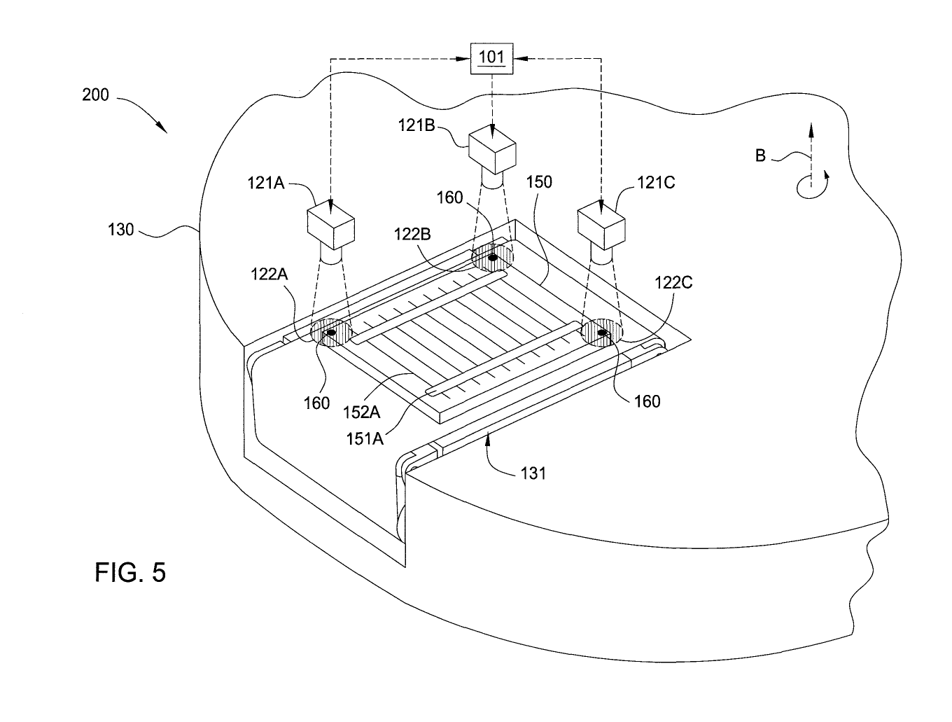

FIG. 5 is a schematic isometric view of one embodiment of the rotary actuator assembly 130 in which the inspection assembly 200 includes a plurality of optical inspection devices. In one embodiment, the inspection assembly 200 includes three cameras 121A, 121B, and 121C that are adapted to view three different regions of the front surface 155 of the substrate 150. In one embodiment, the cameras 121A, 121B, and 121C are each positioned to view a region of the front surface 155 of the substrate 150 having a printed alignment mark 160 contained therein. In this embodiment, the measurement accuracy of the placement of the first layer of buss bars 151A and fingers 152A may be improved due to the ability to reduce the size of each of the respective viewing areas 122A, 122B, and 122C, and thus increase the resolution or number of pixels per unit area, while still allowing the positions of the alignment marks 160 to be spread across the front surface 155 of the substrate 150 as much as possible to reduce the amount of alignment error.

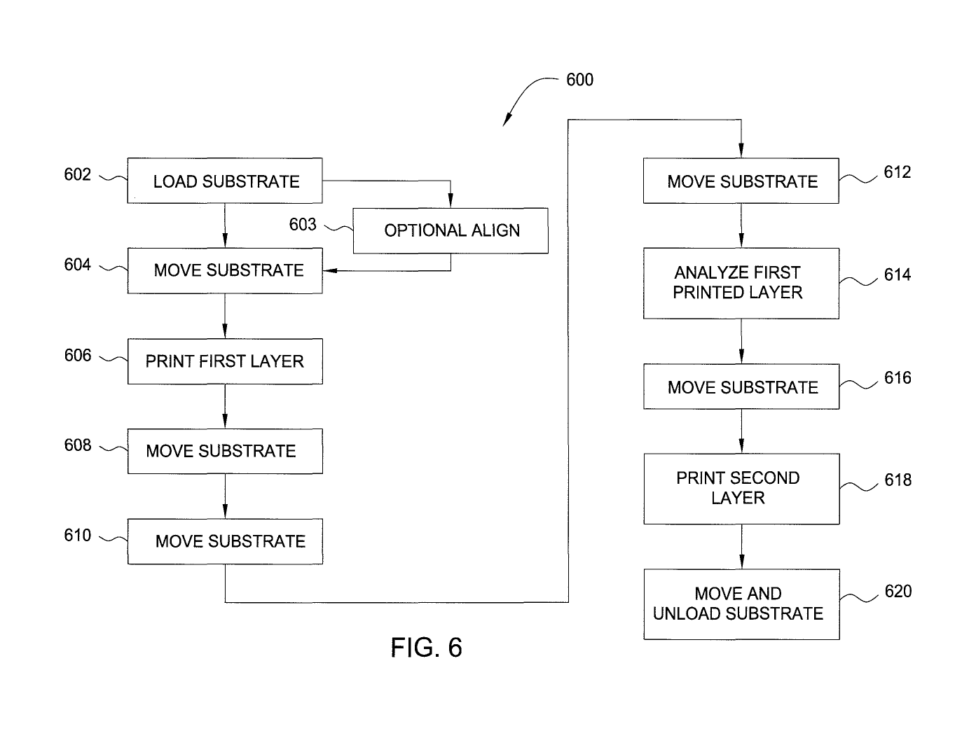

FIG. 6 is a schematic diagram of an operational sequence 600 for accurately screen printing a double layered pattern on the front surface 155 of the substrate 150 according to one embodiment of the present invention. Referring to FIGS. 6, 1A, and 1B, in a substrate loading operation 602, a first substrate 150 is loaded along the path A onto the printing nest 131 located in position “1” of the rotary actuator assembly 130. In an optional first alignment operation 603, the optical inspection assembly 200 may capture images of the blank front surface 155 of the substrate 150, and based on these images, the system controller 101 may configure the screen printing device within the screen printing chamber 102 for printing a pattern on the front surface 155 of the substrate 150. In this operation, the position of the pattern is based on the location of certain features of the substrate 150, such as the edges 150A and 150B of the substrate 150.

In operation 604, the rotary actuator assembly 130 is rotated such that the printing nest 131 containing the loaded substrate 150 is moved in a clockwise direction along a path B1 into position “2” within the printing chamber 102. In operation 606, a first layer of a screen printing pattern, such as buss bars 151A, fingers 152A, and at least two alignment marks 160, is printed on the front surface 155 of the substrate 150. In one embodiment, the three or more alignment marks 160 are printed on the front surface 155 of the substrate 150. In one embodiment, a second substrate 150 is loaded onto the printing nest 131 located in position “1”. In this embodiment, the second substrate 150 follows the same path as the first loaded substrate 150 throughout the operational sequence.

In operation 608, the rotary actuator assembly 130 is rotated such that the printing nest 131 containing the first loaded substrate 150 is moved in a clockwise direction along a path B2 into position “3”. In one embodiment, the printing nest 131 containing the second substrate 150 is moved into position “2” for printing a first layer of the screen printing pattern thereon. In one embodiment, a third substrate 150 is loaded onto the printing nest 131 located in position “1”. In this embodiment, the third substrate 150 follows the same path as the second substrate 150 throughout the operational sequence.

In operation 610, the rotary actuator assembly 130 is rotated such that the printing nest 131 containing the first loaded substrate 150 is moved in a clockwise direction along a path B3 into position “4”. In one embodiment, the printing nest 131 containing the second substrate 150 is moved into position “3”. In one embodiment, the third loaded substrate 150 is moved into position “2” for printing a first layer of the screen printing pattern thereon. In one embodiment, a fourth substrate 150 is loaded onto the printing nest 131 located in position “1”. In this embodiment, the fourth substrate 150 follows the same path as the third substrate 150 throughout the operational sequence.

In operation 612, the rotary actuator assembly 130 is rotated such that the printing nest 131 containing the first loaded substrate 150 is moved in a clockwise direction along a path B4 back into position “1”.

In operation 614, the alignment of the first layer of the screen printing pattern is analyzed. In one embodiment, the optical inspection device 200 captures images of at least two of the alignment marks 160 printed on the front surface 155 of the first substrate 150. The images are read by the image recognition software in the system controller 101. The system controller 101 determines the positional offset (ΔX, ΔY) and the angular offset ΔR of the screen printed pattern by analyzing the at least two alignment marks 160 and comparing them with the expected position (X, Y) and angular orientation R. The system controller 101 then uses the information obtained from this analysis to adjust the position of the screen printing device within the screen printing chamber 102 for subsequent printing of a second layer of the screen printing pattern, such as buss bars 151B and fingers 152B, onto the first layer of the screen printing pattern.

In one embodiment, the optical inspection device 200 captures images of three alignment marks 160 that are disposed on the substrate front surface 155. In one embodiment, the system controller 101 identifies the actual position of the three alignment marks 160 relative to a theoretical reference frame. The system controller 101 then determines the offset of each of the three alignment marks 160 from the theoretical reference frame and uses a coordinate transfer algorithm to adjust the position of the screen printing device within the printing chamber 102 to an ideal position for subsequently printing the second layer of buss bars 151B and fingers 152B with significantly more accurate alignment with respect to the first layer. In one embodiment, the method of ordinary least squares (OLS) or a similar method may be used to optimize the ideal position of the screen printing device for printing the second layer. For instance, the offset of each of the alignment marks 160 from the theoretical reference frame may be determined, and the ideal position of the screen printing device may be optimized according to a function that minimizes the distance between the actual position of the alignment marks 160 and the theoretical reference frame.

In operation 616, the rotary actuator assembly 130 is rotated such that the printing nest 131 containing the first loaded substrate 150 is moved in a clockwise direction along a path B5 back into position “2” within the screen printing chamber 102.

In operation 618, the second layer of the screen printing pattern, such as buss bars 151B and fingers 152B, is printed onto the first layer of the screen printing pattern, such as buss bars 151A and fingers 152A, using the alignment position obtained from the analysis of the operation 614. The alignment mark position information received by the system controller 101 during the operation 614 is thus used to orient and position the second layer of the screen printing material relative to the actual position of the alignment marks 160 created during the formation of the first layer. Therefore, the error in the placement of the second layer is reduced, since the placement of the second layer relies on the actual position of the first layer and not the relationship of the first layer to a feature of the substrate 150, such as the edges 150A and 150B, and the second layer to the feature of the substrate 150. One skilled in the art will appreciate that the placement of the first layer relative to the feature of the substrate 150 and then the second layer relative to the feature of the substrate 150 provides approximately double the error of directly aligning the second layer of the screen printing pattern relative to the first layer of the screen printing pattern.

In operation 620, the rotary actuator assembly 130 is rotated such that the printing nest 131 containing the first loaded substrate 150 is moved in a clockwise direction along a path B6 back into position “3”. In operation 622, the first loaded substrate 150 having a double layered pattern screen printed thereon is unloaded from the printing nest 131 in position “3”. The operational sequence 600 continues until the empty printing nest 131 is back into position “1” again for loading of another substrate 150 wherein the entire sequence is repeated.

In one embodiment, a plurality of processing steps may be performed between operations 604 and 614, such as drying or curing of the first layer, and thus the substrate 150 need not remain positioned on the same printing nest 131. For example, the first layer is disposed on the surface of the substrate 150 using a first system 100 (FIG. 1A) and then the second layer is formed on the substrate 150 in a second system 100. In one configuration, the operations 602-604 are performed in the first system 100 having a first substrate support (e.g., printing nest 131), a first optical inspection device 200, and a first system controller 101, and operations 614-618 are performed in the second system 100 that has a second substrate support (e.g., second printing nest 131), a second optical inspection device 200 and a second system controller 101. In another configuration, the substrate is passed through the same system 100 twice.

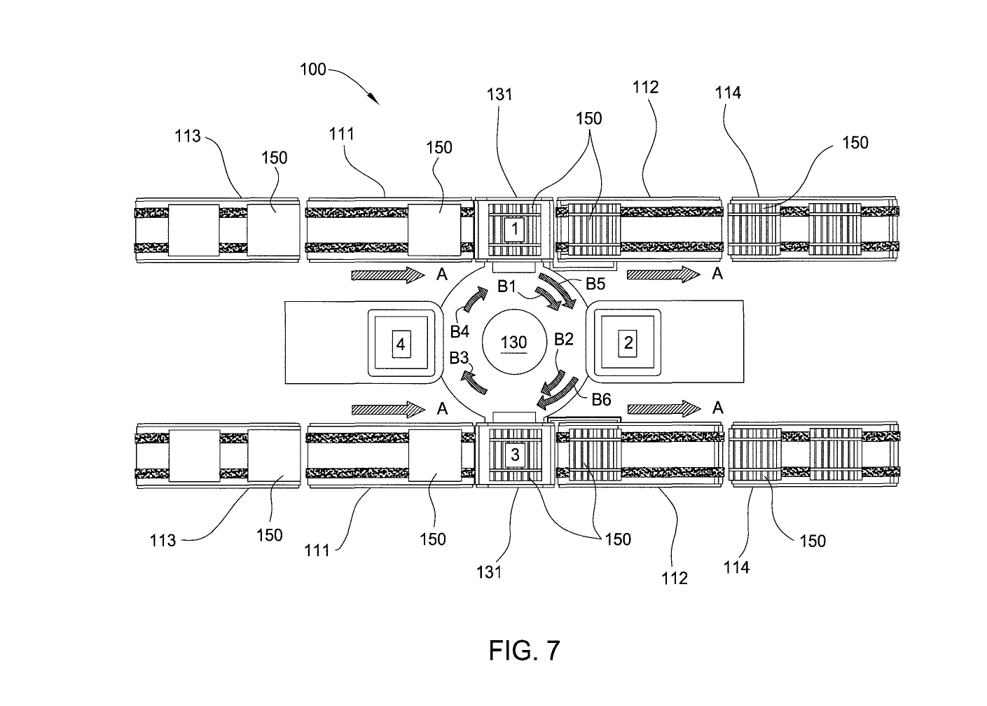

Although embodiments of the present invention are depicted in FIGS. 1A and 1B with respect to a system 100 having a single input and single output, embodiments of the invention are equally applicable to a system 700 having dual inputs and dual outputs as depicted in FIG. 7.

FIG. 7 is a top plan view of a system 700 that may be used in conjunction with embodiments of the present invention to form multiple layers of a desired pattern, such as buss bars 151 and fingers 152, on the front surface 150 of the substrate 150. As shown, the system 700 differs from the system 100 depicted in FIGS. 1A and 1B in that the system 700 includes two input conveyors 111 and two output conveyors 112. The system 700 also differs from the system 100 in that the system 700 includes two screen printing chambers 102. However, the operating sequence of embodiments of the invention with respect to the system 700 is substantially the same as with respect to the system 100. For instance, the operating sequence 600 with respect to the first substrate 150 initially loaded into position “1” is the same as previously described with respect to FIG. 6. However, the operating sequence 600 may run simultaneously with the second substrate 150 initially loaded into position “3”.

Additionally, while embodiments of the present invention are described with respect to a double layered screen printing process, additional embodiments of the invention are equally applicable to screen printing processes having additional layers printed thereon.

While the foregoing is directed to embodiments of the present invention, other and further embodiments of the invention may be devised without departing from the basic scope thereof, and the scope thereof is determined by the claims that follow.

1. A screen printing process, comprising:
receiving a substrate having a first layer of a pattern printed onto a surface of the substrate, wherein the pattern includes at least two alignment marks;
determining the actual position of the at least two alignment marks with respect to at least one feature of the substrate;
comparing the actual position of the at least two alignment marks with an expected position of the at least two alignment marks;
determining an offset between the actual position and the expected position of the at least two alignment marks;
adjusting a screen printing device to account for the determined offset; and
printing a second layer of the pattern onto the first layer of the pattern.

2. The screen printing process of claim 1, wherein the pattern further comprises lines of conductive material.

3. The screen printing process of claim 2, wherein the substrate is polygonal and each of the at least two marks is printed in a different corner region.

4. The screen printing process of claim 1, wherein the determining the actual position of the alignment marks comprises capturing an optical image of the alignment marks and recognizing a physical characteristic of the alignment marks on the optical image.

5. The screen printing process of claim 4, wherein the expected position of the alignment marks is determined with respect to the at least one feature of the substrate prior to printing the first layer.

6. The screen printing process of claim 4, wherein at least three alignment marks are printed on the surface of the substrate.

7. The screen printing process of claim 6, wherein the comparing the actual position of the alignment marks comprises constructing a first reference line between two of the alignment marks and constructing a second reference line between a third alignment mark and the first reference line, wherein the second reference line is perpendicular to the first reference line.

8. The screen printing process of claim 6, wherein the determining the offset comprises measuring the distance between the actual position and the expected position of each alignment mark and computing the offset via a coordinate transfer algorithm.

9. A screen printing process, comprising:
printing a first layer of a pattern onto a surface of a substrate with a screen printing device, wherein the pattern comprises a structure of conductive thin lines and at least two alignment marks;
moving the substrate under an optical inspection assembly;
capturing an optical image of the first layer of the pattern;
determining the actual position of the at least two alignment marks with respect to at least one feature of the substrate;
comparing the actual position of the at least two alignment marks with an expected position of the at least two alignment marks;
determining an offset between the actual position and the expected position;
adjusting the screen printing device to account for the determined offset; and
printing a second layer of the pattern onto the first layer of the pattern via the adjusted screen printing device.

10. The screen printing process of claim 9, further comprising determining the expected position of the alignment marks with respect to the at least one feature of the substrate prior to printing the first layer.

11. The screen printing process of claim 10, wherein the determining the actual position of the alignment marks comprises capturing an optical image of the alignment marks and recognizing a physical characteristic of the alignment marks on the optical image.

12. The screen printing process of claim 11, wherein at least three alignment marks are printed on the surface of the substrate.

13. The screen printing process of claim 12, wherein the comparing the actual position of the alignment marks comprises constructing a first reference line between two of the alignment marks and constructing a second reference line between a third alignment mark and the first reference line, wherein the second reference line is perpendicular to the first reference line.

14. The screen printing process of claim 11, wherein the determining the offset comprises measuring the distance between the actual position and the expected position of each alignment mark and computing the offset via a coordinate transfer algorithm.

15. A screen printing system, comprising:
a rotary actuator having a printing nest disposed thereon and movable between a first position, a second position, and a third position;
an input conveyor positioned to load a substrate onto the printing nest in the first position;
a screen printing chamber having an adjustable screen printing device disposed therein, the screen printing chamber positioned to print a pattern onto the substrate when the printing nest is in the second position, wherein the pattern comprises a conductive structure of thin lines and at least two alignment marks;
an optical inspection assembly having a camera and a lamp, the optical inspection assembly positioned to capture optical images of a first layer of the pattern when the printing nest is in the first position;
an exit conveyor positioned to unload the substrate when the printing nest is in the third position; and
a system controller comprising software configured to determine an offset of an actual position of the alignment marks captured in the optical image of the first layer of the pattern with respect to an expected position of the alignment marks and adjust the screen printing device to account for the determined offset prior to printing a second layer of the pattern on the first layer of the pattern.

16. The screen printing system of claim 15, wherein the optical inspection assembly further comprises a plurality of cameras, and wherein the lamp is configured to direct a beam of light substantially normal to the surface of the substrate positioned under the optical inspection assembly.

17. The screen printing system of claim 16, wherein the system controller further comprises software configured to locate the actual position of the alignment marks with respect to at least one feature of the substrate.

18. The screen printing system of claim 17, wherein the screen printing pattern comprises at least three alignment marks.
